(19) United States
(12) Patent Application Publication
(10) Pub. No.: US 2021/0376844 A1
(43) Pub. Date: Dec. 2, 2021

(54) Event Driven Quasi-Level Crossing Delta Modulator Analog To Digital Converter With Adaptive Resolution

(71) Applicant: Short Circuit Technologies LLC, Rochester, NY (US)

(72) Inventors: Hongying Wang, Cambridge (GB); Filippo Schembari, Dublin (IE); Robert Bogdan Staszewski, Dublin (IE)

(21) Appl. No.: 17/335,930

(22) Filed: Jun. 1, 2021

Related U.S. Application Data
(60) Provisional application No. 63/033,231, filed on Jun. 2, 2020.

(51) Int. Cl. H03M 1/06

(52) U.S. Cl. CPC H03M 1/0617

(57) ABSTRACT

A novel and useful digitally intensive event-driven quasi-level crossing (quasi-LC) delta modulator analog to digital converter (ADC) with adaptive resolution (AR) for Internet of Things (IoT) wireless networks. Minimizing the average sampling rate for sparse input signals significantly reduces the power consumed in data transmission, processing, and storage. The AR quasi-LC delta modulator quantizes the residue voltage signal with a 4-bit asynchronous successive approximation register (SAR) sub-ADC, which enables a straightforward implementation of LC and AR algorithms in the digital domain. The modulator achieves data compression by means of a globally signal dependent average sampling rate and achieves AR through a digital multilevel comparison window that overcomes the tradeoff between the dynamic range and the input bandwidth in conventional LC ADCs. Engaging the AR algorithm reduces the average sampling rate by a factor of three at the edge of the modulator's signal bandwidth.

### REFERENCE TO PRIORITY APPLICATION

This application claims priority to U.S. Provisional Application Ser. No. 63/033,231, filed Jun. 2, 2020, entitled “Adaptive Resolution Quasi Level Crossing Sampling ADC With VCO Based Residue Quantization,” incorporated herein by reference in its entirety.

### FIELD OF THE DISCLOSURE

The subject matter disclosed herein relates to the field of integrated circuits (IC) and more particularly relates to an event driven quasi-level crossing delta modulator analog to digital converter (ADC) with adaptive resolution.

### BACKGROUND OF THE INVENTION

Wireless sensor devices underpin the broad ecosystem of the Internet of Things (IoT), in which the RF transmitter (TX) and digital signal processor (DSP) dominate the power consumption budget. By adopting nanoscale CMOS technology, wireless sensor nodes in a large scale sensor array can achieve inexpensive integration with excellent digital power efficiency. Considering the relatively slow development in energy storage technology and the need for extending the standby time of battery powered wireless sensor nodes, high power efficiency needs to be emphasized and pursued at the analog front end, analog-to-digital converter (ADC), RF TX, and DSP levels.

With the ever increasing number of sensors in an IoT system, more and more sensing data must be converted, processed, transmitted and stored, and therefore the power consumption consumed by the data conversion, processing, transmission and storage unit is significant. In addition, in order to store all the sensed information, more memory hardware becomes necessary.

An emergent way of improving the system power efficiency is to adaptively reduce the average sampling rate of communicated data, thus reducing the power consumed by the RF TX and DSP for the data transmission and processing, respectively.

Considering that the majority of the environmental quantities to be sensed (the information) is sparse in the time domain and bandlimited in the frequency domain, an effective way of reducing power consumption and the amount of memory within an IoT device is to reduce the gross output bit rate from the sensing front end. Over the past several years, several ways have been proposed to achieve such a goal, among which compressive sensing has been suggested as a suitable solution. One way of exploiting it is to use an adaptive sampling technique, which exhibits limited efficiency in reducing the gross output bit rate. An alternative way is to exploit the compressive sensing algorithm in the digital blocks which follow the Nyquist-rate ADC in the sensing front end, which implies higher power consumption and low power scalability versus the input signal activity (an important parameter in signals that are sparse in the time domain). Another alternative way is to exploit the compressive sensing algorithm in the analog front end with a subsequent sub-Nyquist ADC, which has hardware overhead but a suitable way to reduce the gross output bit rate of the sensing front end is to use level crossing sampling. Conventional level-crossing sampling ADCs embed high performance continuous time (CT) comparators, whose comparison's time dispersion versus input voltage derivative is the main limiting factor to system linearity. Moreover, high performance continuous time comparators are rather challenging to be implemented in nanoscale bulk CMOS technology.

Adaptive Nyquist and adaptive oversampling ADCs have been exploited for biopotential signal acquisition, which adopt an adaptive sampling mechanism by adjusting the ADC sampling frequency fₛ based on the slew rate of the input signals. The adjustment of fₛ, however, is between only two frequencies, thus limiting the effectiveness of the average sampling rate reduction. An alternative architecture applies the compressed sensing algorithm to the analog front end circuitry, and then the sub-Nyquist rate ADCs digitize the compressively sampled data. This, however, requires complex hardware in the front end, including a pipelined Nyquist rate programmable switched capacitor (sw-cap) multiplying DAC/integrators and sub-Nyquist rate ADCs. This also results in a complex and more power hungry signal recovery at the receiver side.

There is thus a need for an ADC that overcomes the disadvantages of prior art circuits and that is able to provide improved performance at low cost and low power consumption that would be suitable for use in IoT applications.

### SUMMARY OF THE INVENTION

The present invention is a quasi-LC delta modulator featuring AR and exploiting voltage residue quantization using a 4-bit asynchronous SAR sub-ADC. This promotes shifting the LC detection into the digital domain where the AR and LC algorithms can be straightforwardly implemented as synthesizable logic. By avoiding the use of high performance analog comparators, the timing errors no longer contribute to the ADC SNR, while amplitude quantization does not impair the performance due to the oversampling nature in the residue quantizer of the proposed delta modulator. Its synchronous DT digital output allows to directly interface to conventional DT DSPs. In addition, due to an AR algorithm, the average sampling rate is reduced by a factor of three at the edge of the modulator's signal bandwidth.

The quasi-level crossing sampling ADC replaces high performance continuous time (CT) comparators by shifting the level crossing into the digital domain by using a low resolution residue quantizer. In the digital domain, an adaptive-resolution (AR) algorithm further reduces the gross output bit rate. For the most part, the ADC is implementable with readily synthesizable digital logic using a standard digital synthesis flow. An additional advantage of the ADC over conventional level-crossing sampling ADCs is that it can directly interface to discrete time (DT) DSPs.

The delta-modulator based adaptive-resolution quasi-level crossing sampling (LCS) ADC quantizes its voltage residue by means of a low-resolution sub-ADC (i.e. the residue quantizer) to promote shifting the functionality of a LCS ADC towards the digital domain. This results in a digitally intensive architecture, highly amenable to CMOS process scaling. The functionality of the quasi-LCS ADC mimics the continuous time LCS operation, thus preserving the benefits of an LCS ADC, and allows a straight forward implementation of LCS and adaptive-resolution algorithms in the digital domain, which can be realized as readily synthesizable logic. An additional advantage of this topology is its synchronous output which allows it to be directly interfaced to conventional discrete-time DSPs.

Additional advantages of the ADC structure includes a shift of the functionality of a LCS ADC towards the digital domain, with the benefit of mitigating the negative impact of analog comparators on performance. The ADC exhibits a highly digital implementation, therefore greatly amenable to CMOS process scaling. Due to the digitization of the delta-modulator residue signal V_{RES} using the residue quantizer, the AR-LCS algorithm can be mostly carried out using digital logic. Therefore, the realization of adaptive resolution is nearly costless in terms of hardware resources. Its power scalability with input frequency is still more flexible than in uniform sampling ADCs and conventional LCS ADCs. An additional advantage is its discrete time output, which makes it well suited to directly interface with conventional DT DSPs. Further, due to the adoption of an adaptive resolution algorithm, the gross output bit rate can be reduced by three at the edge of the signal bandwidth compared to a fixed resolution LCS ADC with no appreciable signal-to-quantization noise ratio (SQNR) degradation.

In addition, the ADC has applicability in terms of power efficiency whenever compressed sensing is needed to perform medium to low resolution quantization of signals which are sparse in the time domain and band limited in the frequency domain, such as ECG, EEG, etc.

In one embodiment, the modulator is fabricated in 28 nm CMOS and achieves a peak SNDR of 53 dB over a signal bandwidth of 1.42 MHz while consuming 205 μW and an active area of 0.0126 mm².

There is thus provided in accordance with the invention, an analog to digital converter (ADC) circuit, comprising a subtractor operative to subtract an analog feedback signal generated by a digital to analog converter (DAC) from an input voltage signal to generate a residue signal, a residue quantizer operative to convert said residue signal from an analog to digital domain, an event detector operative to detect when said residue signal crosses one of a plurality of levels, and an up/down counter operative to increment and decrement a digital output in accordance with said level crossing detection, said digital output fed back to an input of said DAC.

There is also provided in accordance with the invention, an analog to digital converter, comprising a subtraction node adapted to subtract the output of a feedback digital to analog converter (DAC) from an input voltage signal, a residue amplifier adapted to amplify the output of said subtraction node, a residue quantizer adapted to convert the output of said residue amplifier from analog to digital domain, and an adaptive resolution circuit incorporating a delta modulator circuit and adapted to perform level crossing and adaptive resolution algorithms in the digital domain to generate a digital output therefrom.

There is further provided in accordance with the invention, a method of analog to digital conversion, the method comprising subtracting an analog feedback signal generated by a digital to analog converter (DAC) from an input voltage signal to generate a residue signal, converting said residue signal from an analog to digital domain, detecting when said residue signal crosses one of a plurality of levels, and incrementing or decrementing a digital output in accordance with said level crossing detection, said digital output fed back to an input of said DAC.

### BRIEF DESCRIPTION OF THE DRAWINGS

The present invention is explained in further detail in the following exemplary embodiments and with reference to the figures, where identical or similar elements may be partly indicated by the same or similar reference numerals, and the features of various exemplary embodiments being combinable. The invention is herein described, by way of example only, with reference to the accompanying drawings, wherein:

FIG. 1A is a block diagram illustrating a delta modulator based ADC circuit;

FIG. 1B is a block diagram illustrating a flash based level crossing ADC circuit;

FIG. 1C is a block diagram illustrating an example quasi-level crossing ADC circuit;

FIG. 1D is a block diagram illustrating an equivalent circuit of the ADC of FIG. 1C with continuous time analog comparators;

FIG. 1E is a schematic diagram illustrating the preamplifier of the circuit of FIG. 1C in more detail and its corresponding linear model;

FIG. 1F is a diagram illustrating an example of uniform sampling in an ADC;

FIG. 1G is a diagram illustrating an example of level crossing in an ADC;

FIG. 1H is a diagram illustrating an example of quasi-level crossing in an ADC;

FIG. 2A is a diagram illustrating an example logarithmic signal sampled and converted with the modulator of the present invention without using an adaptive resolution (AR) algorithm;

FIG. 2B is a diagram illustrating an example logarithmic signal sampled and converted with the modulator of the present invention using an adaptive resolution (AR) algorithm;

FIG. 3 is a block diagram illustrating an example AR quasi-level crossing delta modulator ADC constructed in accordance with the present invention;

FIG. 4 is a diagram illustrating an example binary-weighted 7-bit DAC with sw-cap subtractor;

FIG. 5 is a diagram illustrating timing and control signals for the DAC circuit of FIG. 4;

FIG. 6 is a diagram illustrating an example implementation of the preamplifier circuit portion of the ADC circuit;

FIG. 7 is a diagram illustrating an example implementation of the residue quantizer portion of the ADC circuit;

FIG. 8 is a diagram illustrating the logic flow of the synthesized digital block portion of the ADC;

FIG. 9 is a diagram illustrating the timing diagrams corresponding to the flow diagram of FIG. 8;

FIG. 10A is a diagram illustrating measured digital output D_{OUT} signals for an example ECG signal pattern;

FIG. 10B is a diagram illustrating event based output signal \tilde{Δ} for an example ECG signal pattern;

FIG. 10C is a diagram illustrating event based output signal CNG for an example ECG signal pattern;

FIG. 11 is a block diagram illustrating an example mobile device incorporating the event driven quasi-level crossing delta modulator ADC of the present invention; and

FIG. 12 is a block diagram illustrating an example IoT node incorporating the event driven quasi-level crossing delta modulator ADC of the present invention.

### DETAILED DESCRIPTION

In the following detailed description, numerous specific details are set forth in order to provide a thorough understanding of the invention. It will be understood by those skilled in the art, however, that the present invention may be practiced without these specific details. In other instances, well-known methods, procedures, and components have not been described in detail so as not to obscure the present invention.

Among those benefits and improvements that have been disclosed, other objects and advantages of this invention will become apparent from the following description taken in conjunction with the accompanying figures. Detailed embodiments of the present invention are disclosed herein. It is to be understood, however, that the disclosed embodiments are merely illustrative of the invention that may be embodied in various forms. In addition, each of the examples given in connection with the various embodiments of the invention which are intended to be illustrative, and not restrictive.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

The figures constitute a part of this specification and include illustrative embodiments of the present invention and illustrate various objects and features thereof. Further, the figures are not necessarily to scale, some features may be exaggerated to show details of particular components. In addition, any measurements, specifications and the like shown in the figures are intended to be illustrative, and not restrictive. Therefore, specific structural and functional details disclosed herein are not to be interpreted as limiting, but merely as a representative basis for teaching one skilled in the art to variously employ the present invention. Further, where considered appropriate, reference numerals may be repeated among the figures to indicate corresponding or analogous elements.

Because the illustrated embodiments of the present invention may for the most part, be implemented using electronic components and circuits known to those skilled in the art, details will not be explained in any greater extent than that considered necessary, for the understanding and appreciation of the underlying concepts of the present invention and in order not to obfuscate or distract from the teachings of the present invention.

Any reference in the specification to a method should be applied mutatis mutandis to a system capable of executing the method. Any reference in the specification to a system should be applied mutatis mutandis to a method that may be executed by the system.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermediary components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Throughout the specification and claims, the following terms take the meanings explicitly associated herein, unless the context clearly dictates otherwise. The phrases “in one embodiment,” “in an example embodiment,” and “in some embodiments” as used herein do not necessarily refer to the same embodiment(s), though it may. Furthermore, the phrases “in another embodiment,” “in an alternative embodiment,” and “in some other embodiments” as used herein do not necessarily refer to a different embodiment, although it may. Thus, as described below, various embodiments of the invention may be readily combined, without departing from the scope or spirit of the invention.

In addition, as used herein, the term “or” is an inclusive “or” operator, and is equivalent to the term “and/or,” unless the context clearly dictates otherwise. The term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In the claims, any reference signs placed between parentheses shall not be construed as limiting the claim. The use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first,” “second,” etc. are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

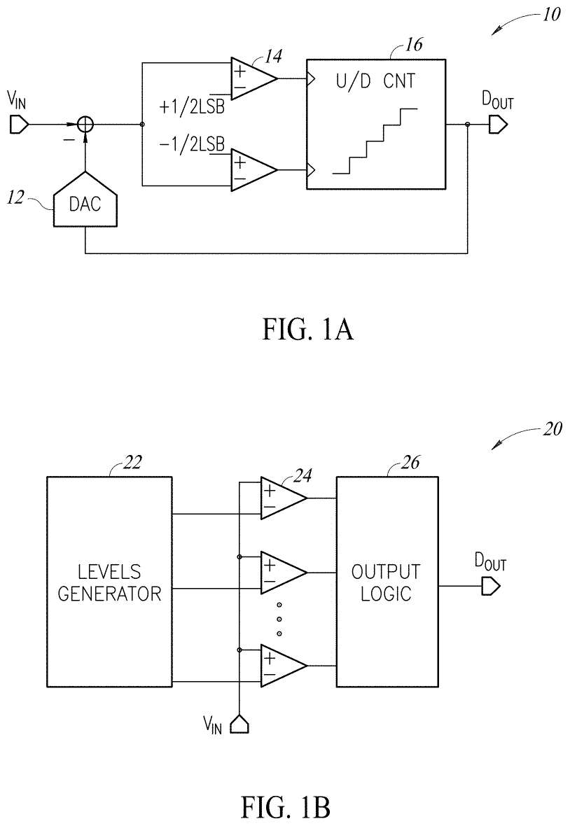

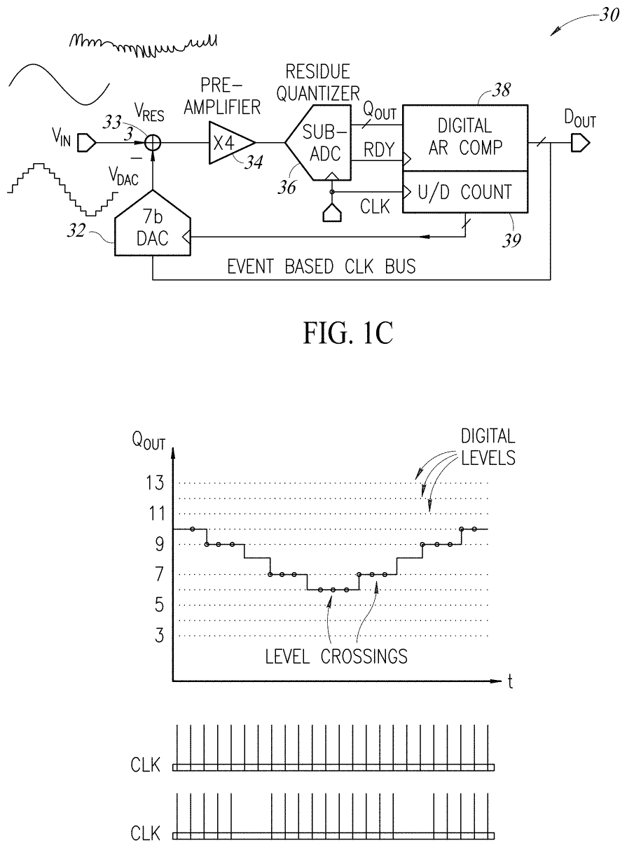

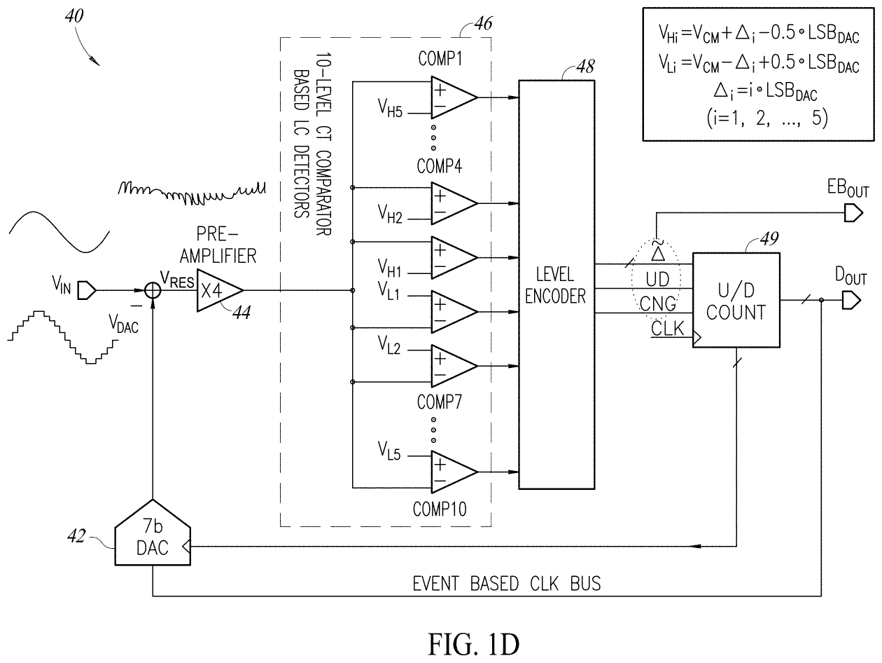

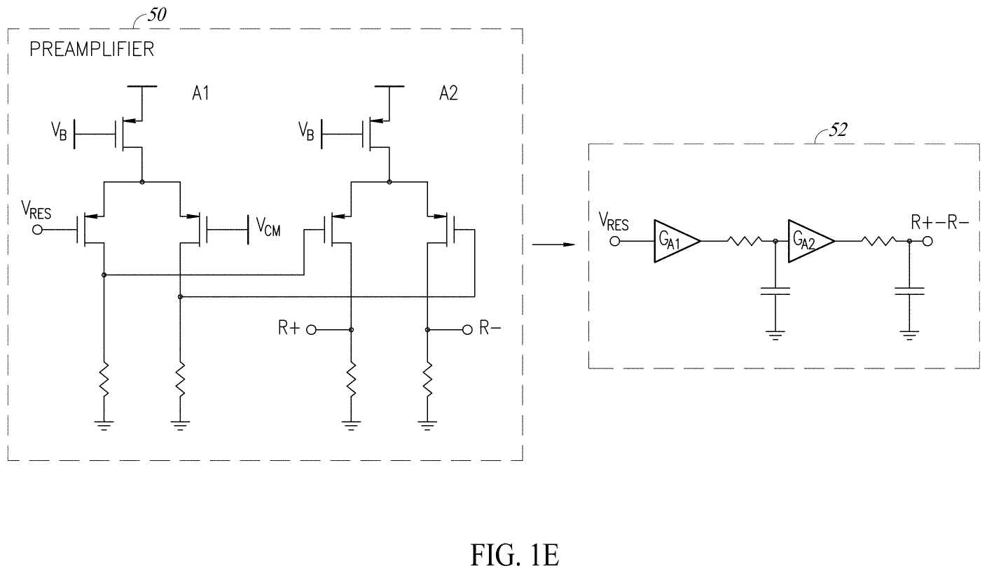

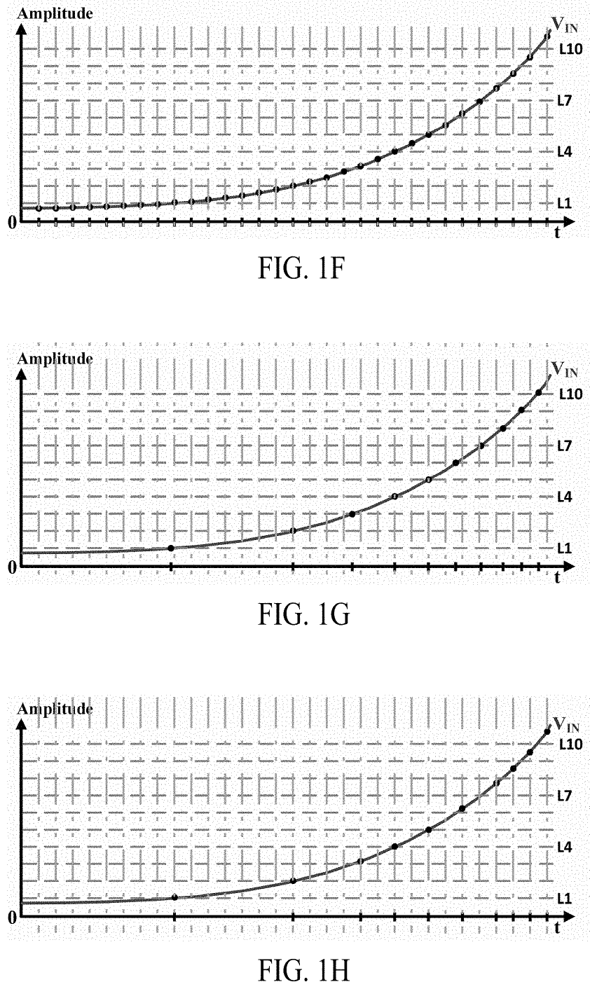

In one embodiment, level-crossing sampling (LCS) can be used where the input signal is sampled and converted into the continuous-time (CT) domain only when it crosses specific threshold levels. The average sampling rate of LC ADCs is therefore signal dependent, in contrast to uniform sampling ADCs. The delta modulator based ADC (FIG. 1A) and the flash-based ADC (FIG. 1B) are two LC ADC topologies. Both of them generally use high performance CT comparators to realize threshold crossing detectors. The delta modulator based ADC, generally referenced 10, comprises a DAC 12, two comparators 14 and up/down (U/D) count logic 16. The flash-based ADC, generally referenced 20, comprises an array of comparators 24, levels generator circuit 22, and output logic 26.

Uniform sampling as shown in FIG. 1F samples the input signal at a fixed clock frequency and the sampled signal can be expressed as (V_{IN}(tᵢ), tᵢ) with a constraint tᵢ=n/f_{S}, where n is an integer number and f_{S} is the clock frequency. Uniform sampling may suffer from aliasing issues and an anti-aliasing filter is needed if larger interferers exist at the input.

Level-crossing sampling (LCS) as shown in FIG. 1G samples the input signal only when it crosses specific threshold levels and the sampled signal can be expressed as (V_{IN}(tⱼ), tⱼ), where V_{IN}(tⱼ) is a specific threshold level and tⱼ is in continuous time (CT) domain. For LCS, the accuracy of tⱼ is dependent on the propagation delay (and its dispersion) of the threshold detectors.

By comparing these two cases, a conclusion can be drawn that LCS can adjust the sampling rate based on the input signal activity, such that it reduces the sampling rate when the input signal varies slowly and maintains a higher sampling rate when the input signal varies rapidly.

A method of quasi-LC sampling, shown in FIG. 1H, is different from LCS, in that the level-crossing is performed in the sampled ‘digital’ domain. The (over)-sampled signal can be expressed as (V_{IN}(tⱼ), tⱼ) with (tⱼ=n/f_{S}), where n is an integer number and f_{S} is the (oversampling) clock frequency.

With reference to the circuits of FIGS. 1A and 1B, it is challenging to implement these two circuits in deep nanoscale CMOS given the low intrinsic gain of transistors and more importantly the propagation delay dispersion that is signal dependent in most cases which ultimately impairs the ADC linearity. Moreover, a purely CT approach cannot directly interface to conventional discrete time (DT) DSPs, demanding time domain quantization that leads to quantization noise. Otherwise, in one embodiment, a custom designed CT DSP is required to process the CT digitized data. To take advantage of the technological scaling VCO-based topologies can be used to avoid the use of high performance CT comparators. The phase of the VCO, however, keeps increasing with time and causing a continual triggering of level-crossing (LC) events. As a consequence, this approach appears less suitable for compressed sensing applications. Alternative sampling techniques based on LCS can be used such as the derivative LCS and the adaptive resolution LCS (AR LCS).

AR LCS can further reduce the average sampling rate of an LC ADC by adaptively tuning the ADC resolution (LSB step) depending on the input signal derivative while avoiding the degradation of its in-band performance. A fast changing input can be tracked and converted without a slew rate overload, meaning that the signal bandwidth can be extended by the AR technique. The delta modulator based architecture implements the AR algorithm with a time varying comparison window that is reduced gradually (from 7 to 1 LSB) using control signals generated by delay cells and two DACs that can generate the variable comparison intervals. All of them, however, lead to a significant hardware overhead. In one embodiment, the AR algorithm is verified in a field programmable gate array (FPGA). It uses a 16-bit counter in the FPGA, however, that operates at a frequency with an OSR of 500, which is not a practical solution for an IoT node.

In another embodiment, an AR delta modulator is disclosed that quantizes its voltage residue V_{RES} by means of a low resolution sub-ADC (hereafter also referred to as “residue quantizer”). This allows a straight forward implementation of LC and AR algorithms in the digital domain, which can be realized as readily synthesizable logic. Differently from conventional LC ADCs, the delta modulator of the present invention exploits the LC algorithm in the sampled digital domain, hence the “quasi-LC” terminology. A current trend for highly integrated wireless sensor devices is to implement the analog front end, RF TX, and DSPs in nanoscale CMOS technologies. The quasi-LC delta modulator can also be similarly implemented and enables a relatively simple implementation of the compressed sensing.

### Residue-Quantizing Delta Modulator ADC

To reduce the power consumed in data transmission, processing and storage and reduce memory hardware requirements by reducing the gross output bit rate of wireless sensor devices in the broad ecosystem of the Internet-of-Things (IoT), the aforementioned level-crossing sampling (LCS) ADC technique can be further improved to exploit compressive sensing. In one embodiment, the delta modulator based LCS ADC removes the high performance continuous time (CT) comparators by shifting the level-crossing sampling paradigm towards the digital domain, by means of a highly digital implementation. To exploit such a paradigm shift, the residue voltage in the delta-modulator based LCS ADC is digitized with a low resolution quantizer (referred to as a residue quantizer) that is implemented in one example embodiment as a 4-bit SAR ADC. This allows a straightforward implementation of LCS and adaptive resolution algorithms in the digital domain, which can be realized as readily synthesizable digital logic.

An example embodiment of the AR delta modulator is shown in FIG. 1C. The ADC, generally referenced 30, comprises a DAC 32, subtractor 33, preamplifier 34, sub-ADC 36, digital AR comparator 38, and U/D count logic 39.

Unlike prior art LC delta modulators, the modulator of the present invention digitizes the delta modulator residue V_{RES} using a low resolution sub-ADC, thus enabling the AR-LC algorithm to be carried out in the digital domain. Therefore, the realization of AR is nearly costless in terms of hardware resources. The equivalent topology of the modulator using flash/parallel CT comparators is shown in FIG. 1D where the circuit, generally referenced 40, comprises DAC 42, preamplifier 44, comparator based level detectors 46, level encoder 48, and U/D count logic 49.

With reference to FIGS. 1C and 1D, the modulator comprises analog/mixed-signal and digital portions. The analog/mixed-signal portion includes the 7-bit sw-cap feedback DAC 32, subtractor 33 (here, event-based sampled discrete time (DT), but generally it could be continuous time (CT)), pre-amplifier 34, and the 4-bit residue quantizer 36. The digital portion includes synthesized logic and a custom digital section. After the subtraction node, the pre-amplifier 50, which consists of two cascaded low-gain amplifiers (shown in FIG. 1E), is used to amplify the residue V_{RES} signal by 4× to compensate for the gain loss of the passive subtractor and to drive the 4-bit residue quantizer. Note that the feedback DAC is shown in FIGS. 1C, 1D, 3, and 4 as a 7-bit DAC for illustration purposes only. It is appreciated that an n-bit DAC having any desired number of bits can be used depending on the particular implementation.

The synthesized logic serves the purpose of multi-threshold comparison (hence the name AR Comp) of the quantized residue signal, moreover exploiting the LC and AR algorithms and performing up/down counting (U/D COUNT) to generate the binary digital control for the sw-cap feedback DAC. The sw-cap feedback DAC and subtractor are triggered by an event-based CLK bus, generated by gating off the system CLK with the LC events generated in the AR Comp, while the sub-ADC and U/D COUNT are clocked by CLK.

The AR Comp compares the digitized V_{RES} with multiple digital threshold levels (i.e. 10 in this example embodiment). When the residue voltage V_{RES} is within the range of V_{CM}±LSB_{DAC}/4, where V_{CM} is the common mode voltage of the subtractor and LSB_{DAC} is the LSB of the sw-cap DAC, the output of the residue quantizer Q_{OUT} stays at 8, and no level crossings are detected by the AR Comp. When V_{RES} exceeds this range, it indicates that one among the ten digital levels (3, 4, . . . 7 and 9, 10, . . . 13) is crossed. This will trigger the event and will enable the event based CLK bus.

EB_{OUT} comprises the trigger CNG, which goes high if a level is crossed, signal UD, which indicates whether V_{IN} is increasing or decreasing, and \tilde{Δ}, which instead indicates the magnitude of the shift that D_{OUT} experienced during the CLK period. A custom control logic generates the event based gating triggers synchronous to CNG, which are used to control the sw-cap feedback DAC and subtractor.

The circuit 40 exploits ten high performance CT comparators to compare V_{RES} versus ten different threshold levels (i.e. resembling the operation of a ten level LC flash ADC), thus performing AR LC detection without the need of a slope detector. The subsequent CT digital circuitry, marked as level encoder 48 in FIG. 1D, controls the U/D counter 49 based on the highest (or lowest) level that is crossed. In contrast, the modulator completely avoids multiple high performance CT comparators and multilevel reference voltages by adopting a successive approximation register (SAR) sub-ADC, which digitizes the V_{RES} signal, and by then performing the multi-threshold comparison in the digital domain.

### Comparison to Clockless LC ADCs

Embodiments of LC ADCs that are generally clockless are shown in FIGS. 1A and 1B as described supra, with the following digital block triggered by events from the CT comparators. Note that the output D_{OUT} is a time domain signal in which the information is not only in the actual digital value represented by the logic signal levels on the bus but also in the transition timestamps, which are real-valued. For a one-bit time domain signal, the information is contained in the time at which the zero to one (or one to zero) happens. For a multibit time domain signal, the information is the time at which a code transition happens. The advantages of these clockless LC ADCs is that they are fast in terms of the output updating to respond to input changes, have input dependent output bit rate and dynamic power consumption, have lower in-band quantization error, and have an alias free nature. Furthermore, the timestamp information in these clockless LC ADCs has theoretically perfect precision when using ideal components.

The former two of these advantages are due to the inherent input dependent oversampling behavior of the ADCs. In the example of a sinusoidal signal converted at a fixed resolution, the oversampling ratio of a CT LC ADC can be expressed as

$${OSR}_{CT \text{-} LC} = \frac{{f}_{out}}{2 \cdot {f}_{in}} = \frac{{A}_{i n , pp}}{FS} \cdot {N}_{level} \qquad ( 1 )$$

where fₒᵤₜ is the average sampling rate, fᵢₙ is the frequency of the sinusoidal input, A_{in,pp} is the input peak-to-peak amplitude, FS is the ADC full scale range, and Nₗₑᵥₑₗ is the number of quantization levels of the LC ADC corresponding to 2^{N} for a delta modulator with an N-bit feedback DAC, and to the number of comparators for the flash topology. For the quasi-LC delta modulator, it is observed that from a black box perspective, it resembles the operation of a clockless CT LC ADC as it also oversamples the input signals with an input dependent oversampling ratio, thus responding to input changes almost immediately, thereby achieving signal dependent output bit rate and dynamic power consumption.

In terms of in-band error, the modulator of the present invention has different dominant contributors compared to clockless LC ADCs, whose main sources of inaccuracy are amplitude and timing errors. The amplitude errors arise from the uncertainty in the position of the threshold levels due to mismatches in reference generator and to the offset of CT comparators, while the timing errors arise from the finite time resolution of the time quantizer that is based on the oversampling clock. Neglecting the amplitude errors, which can be calibrated, the SNR of clockless CT LC ADC can be expressed as a function of time quantization.

SNR_{Δt,dB}=20 log₁₀(R)−14.2 (2)

where R is the timing resolution ratio, defined as (fᵢₙ·Δtₑ)⁻¹, in which fᵢₙ is the input signal frequency and Δtₑ is the absolute timing error, represented by the loop delay variation (Δt_{L}) in the delta modulator topology. Such an error is mainly due to the propagation delay dispersion of the CT comparators that are sensitive to the input voltage derivative, and thus, ultimately represents the main nonlinearity impairment of CT LC ADCs. The modulator exploits an alternative method of performing LC sampling, which is reasonably insensitive to the effects of absolute timing errors, here represented by the absolute time jitter of the sub-ADC clock, which is reasonably lower than Δt_{L} and furthermore not signal dependent. Unlike CT LC ADCs, the amplitude quantization noise from the residue quantizer contributes to the quasi-LC delta modulator SNR (i.e. noise floor). Such contribution, however, is mitigated by the oversampling in the sub-ADC, and hence, the modulator can also achieve a low in-band error.

In terms of aliasing, unlike clockless and alias free LC ADCs, the quasi-LC modulator of the present invention locally performs the uniform sampling of the amplified V_{RES} right at the sub-ADC. Similar to uniform sampling ADCs, if large interferers are expected at the input signal, then the use of an input anti-aliasing pre-filter in front of the modulator might be unavoidable. Due to the heavy oversampling in the sub-ADC, however, the specifications of such a pre-filter can be relaxed.

Despite losing the ideal aliasing free characteristic inherent with clockless LC ADCs, the modulator of the present invention introduces two alternative advantages. The first is the digitally intensive nature of the AR-LC algorithm, exploited with the aid of the residue quantization. This relieves the design from the sensitivity to the propagation delay dispersion of comparators and also ensures amenability with nanoscale CMOS technology nodes. The second advantage is the modulator digital output being updated synchronously to the local clock, therefore allowing the quasi-LC delta modulator to directly interface with the DT DSPs.

### System Level Analysis

The two cascaded low gain amplifiers in the preamplifier function as a second order RC low pass filter (LPF) 52 as shown in FIG. 1E, whose z-domain transfer function can be expressed as

$${H}_{LPF} ( z ) = \frac{{G}_{A} \cdot ( 1 - {p}_{1} ) \cdot ( 1 - {p}_{2} )}{( 1 - {p}_{1} {z}^{- 1} ) \cdot ( 1 - {p}_{2} {z}^{- 1} )} \qquad ( 3 )$$

where G_{A} is the overall dc gain of the preamplifier, while p₁ and p₂ are the dominant poles, generated by the two cascaded low gain amplifiers. By defining α as the ratio between the LSB of the sw-cap DAC (LSB_{DAC}) and the LSB of the residue quantizer sub-ADC (LSB_{sub-ADC}), nominally unity, the z-domain transfer functions to the system output D_{OUT} of the quantization noise E_{Q} of the residue quantizer (NTF) and of the input signal V_{IN} (STF) can be expressed as

$$\begin{matrix}NTF ( z ) = \frac{{D}_{OUT}}{{E}_{Q}} = \frac{1}{1 - {z}^{- 1} + {z}^{- 1} \cdot α \cdot {G}_{S} \cdot {H}_{LPF} ( z )} \\ and & ( 4 ) \\ STF ( z ) = \frac{{D}_{OUT}}{{V}_{IN}} = \frac{α \cdot {G}_{S} \cdot {H}_{LPF} ( z )}{1 - {z}^{- 1} + {z}^{- 1} \cdot α \cdot {G}_{S} \cdot {H}_{LPF} ( z )} & ( 5 )\end{matrix}$$

where G_{S} is the gain of the subtractor that immediately precedes the amplifier (equal to ¼ in this example embodiment). Any mismatch between LSB_{DAC} and LSB_{sub-ADC} can be treated as a gain error, described by a value of α different than 1. The poles of the LPF are located at a nominal frequency p₀ of 10 MHz, which is considerably higher than the signal bandwidth of 1.42 MHz, and almost an order of magnitude lower than the frequency of the oversampling clock CLK (f_{CLK}). As the in-band NTF is equal to 0 dB, the in-band noise floor of the modulator output spectrum only depends on LSB_{sub-ADC} and on the chosen oversampling ratio given that the in-band quantization noise power from the residue quantizer is inversely proportional to it.

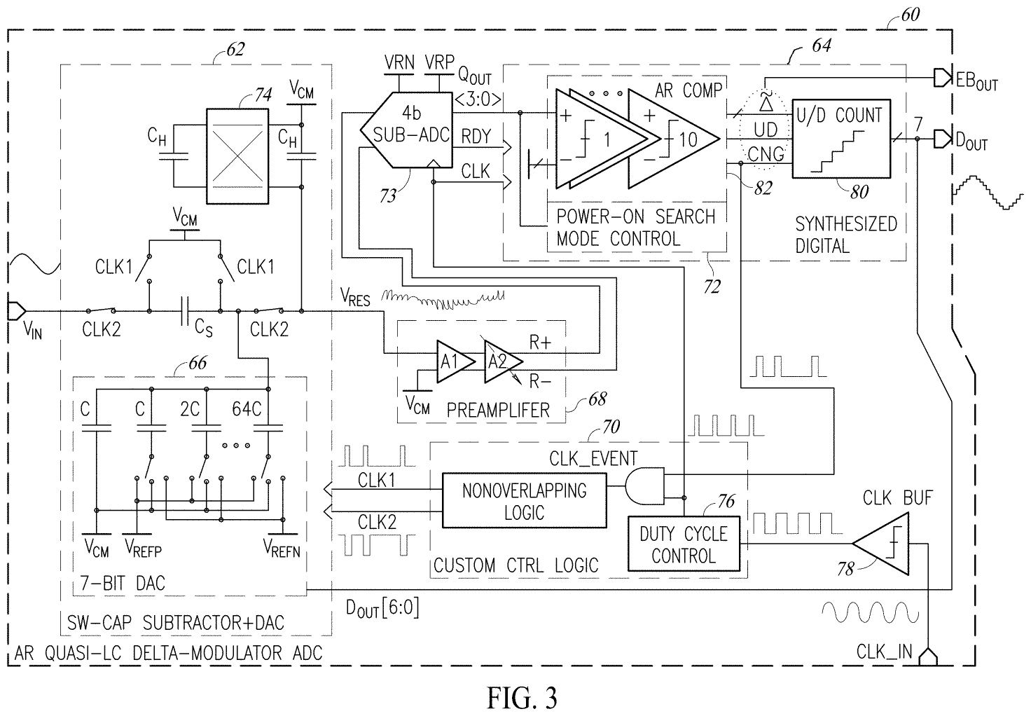

A block diagram illustrating an example AR quasi-level crossing delta modulator ADC constructed in accordance with the present invention is shown in FIG. 3. The ADC, generally referenced 60, comprises sw-cap subtractor 62 and DAC 66, preamplifier 68, synthesized digital circuit 64, U/D counter circuit 80, power-on search mode control 72, custom control logic 70, duty cycle control 76, clock buffer 78, and sub-ADC 73.

The adaptive-resolution delta-modulator LCS ADC is shown in FIG. 1C. It comprises both an analog (mostly realized using mixed-signal circuits) and a digital section. The former comprises a switched-capacitor (sw-cap) feedback DAC 32 and subtractor 33, residue pre-amplifier 34 and 4-bit residue quantizer 36. The latter comprises instead both the synthesized logic operating as an adaptive-resolution (AR) comparator (AR Comp) 38, which performs the LCS and AR algorithm in the digital domain, and the Up/Down counter (U/D COUNT) 39 to generate the binary digital control for the sw-cap feedback DAC. The sw-cap feedback DAC and subtractor are controlled by the event-based CLK, which is gated off by the level crossing events generated in the AR Comp, while the sub-ADC and U/D COUNT are clocked by CLK. After the subtraction node, the residue amplifier which consists of two cascaded low gain amplifiers with passive load, is used to amplify by 4× the residue as well as to drive the 4-bit residue quantizer.

Differently from clockless delta-modulator based LCS ADCs, the proposed ADC, whose equivalent topology is shown in FIG. 1D, digitizes the delta-modulator residue signal V_{RES} using a low resolution sub-ADC such that the AR-LCS algorithm can now be mostly carried out using digital logic. Therefore, the realization of adaptive resolution is nearly costless in terms of hardware resources. The AR Comp compares the digitized V_{RES} with multiple digital threshold levels (up to 10 in the example ADC). The implemented adaptive-resolution algorithm allows a further reduction of the gross output bit rate.

From Equations 4 and 5, it is possible to quantify the effects that variations in the values of Gₜₒₜₐₗ, p₁, and p₂ have on the magnitude of STF and NTF. A ±25% variation of Gₜₒₜₐₗ relative to its nominal value does not impact the in-band STF magnitude, while it causes approximately a ±2.5-dB variation in the in-band quantization noise power. Another parameter of interest in the modulator transfer function is the magnitude of a peak at around 10 MHz, since the signal harmonics, potential interferers, and the quantization noise around that frequency experience a 5 to 10 dB amplification (although not impairing the modulator performance, since it is substantially above the signal bandwidth of the modulator).

In face of a Gₜₒₜₐₗ variation of ±25% the out-of-band peak magnitude of the STF and NTF will vary by approximately ±2.5 and ±1 dB, respectively, without incurring any appreciable phase margin deterioration. This out-of-band peak can also be reduced by pushing p₁ and p₂ to higher frequencies, but this will degrade the low pass filtering performance. A ±20% variation of p₁ and p₂ from the nominal frequency p₀=10 MHz results in about −1.5/+2 dB and −1/+1.5 dB variation in the out of band peak magnitude of the NTF and STF, respectively.

In terms of distortion, i.e. total harmonic distortion (THD), system level behavioral modeling simulations of the proposed modulator without considering circuit level nonidealities (e.g., parasitics, mismatches, and leakage) show that the THD degrades gradually when Gₜₒₜₐₗ decreases, and a 25% decrease of Gₜₒₜₐₗ relative to its nominal value can lead to a 2.5 dB THD degradation. PVT variations also produce uncertainty in the pole frequencies and signal path gain, introducing the need for tunability within the pre-amplifier.

### Adaptive Resolution (AR) Algorithm

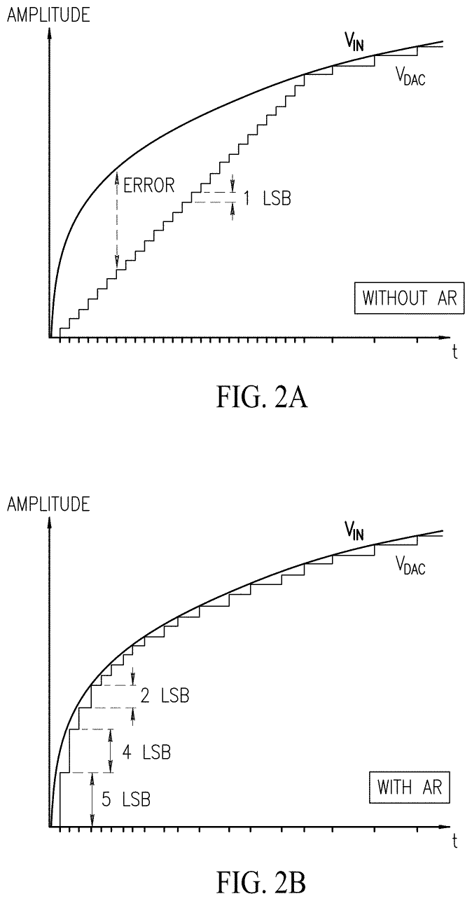

The AR algorithm is operative to further reduce the average sampling rate so as to lower the power consumed for processing and wirelessly transmitting the data from the IoT node. It is exploited by adjusting the threshold intervals based on the input signal activity (i.e. derivative) without sacrificing ADC in-band performance. A slowly varying input signal is converted with the finest resolution (Δₘᵢₙ=1 LSB), while a fast varying signal is converted with the coarsest resolution (Δₘₐₓ=5 LSB, as an example), which can be observed from the example shown in FIGS. 2A and 2B. For prior art LC delta modulators without an AR algorithm, the delay introduced by the loop must be kept shorter than the time needed for a −3 dBFS sinusoidal input (amplitude indicated as A_{-3 dB}) at the edge of the signal bandwidth (BW) to cross two consecutive threshold levels, whose distance is Δₘᵢₙ. In other words, the loop must react fast enough to track quick variations of the input signal. Otherwise, the signal V_{DAC} would entail a large voltage error during the fast varying part of the input signal, as shown in FIG. 2A.

Therefore, a specification on the maximum allowed loop delay t_{L,max} of an LC delta modulator without the AR algorithm, which therefore has a fixed resolution (equal to Δₘᵢₙ), can be derived

$${t}_{L , max} = \frac{Δ}{2 π \cdot BW \cdot {A}_{- 3 dB}} . \qquad ( 6 )$$

Consequently, the signal bandwidth is upper-bounded at

$${BW}_{max} = \frac{Δ}{2 π \cdot {t}_{L , max} \cdot {A}_{- 3 dB}} . \qquad ( 7 )$$

The direct proportionality to the LC ADC resolution indicates that by exploiting the AR up to the coarsest value Δₘₐₓ, BWₘₐₓ and the maximum slew rate that can be tracked can extend by a factor L=Δₘₐₓ/Δₘᵢₙ (hereinafter referred to as the AR factor).

A way of implementing the AR in a conventional CT LC delta modulator is to adaptively tune, in a time varying fashion, the comparison interval (i.e. the difference between the upper and lower comparison thresholds of the two comparators that sense the residue voltage, V_{H} and V_{L}), based on the input signal derivative. This leads, however, to hardware overhead. Logically, the quasi-LC delta modulator replaces the two comparators of the CT delta modulator, each with time varying thresholds, with 2L comparators each with a fixed threshold, with reference to FIG. 1D.

In one embodiment, the multi-threshold comparison is performed in the digital domain by the AR Comp, implemented as readily synthesizable logic. The highest number \tilde{Δ} of comparison thresholds that are crossed within a certain time window T_{W} determines the magnitude of the shift that D_{OUT} needs to undertake. As a consequence, the residue voltage V_{RES} needs to be first digitized, which is the task of the residue quantizer, the 4-bit SAR sub-ADC. The use of a local (oversampling) clock signal is then unavoidable, and its period sets both the above mentioned value of T_{W} and the loop delay t_{L}, which now becomes fixed and independent of the input signal. It is noted that although a uniformly sampled sub-ADC is adopted here for residue quantization, the invention is among the best in class in AR LC ADCs, both in terms of loop delay dispersion and power efficiency. Indeed, for nanoscale CMOS technologies, the use of CT high performance comparators, which commonly adopt a multistage topology to achieve sufficient gain, likely results in higher static power consumption, which needs to be traded off with the bandwidth and therefore the loop delay dispersion.

As CLK is applied to the residue quantizer, the signal bandwidth of the quasi-LC delta modulator is constrained by the fact that the maximum voltage shift that the feedback DAC is able to provide within T_{CLK} corresponds to the coarsest resolution allowed by the AR scheme Δₘₐₓ. This means that the product Δₘₐₓ·f_{CLK} represents the maximum absolute value of the signal derivative that the ADC is able to handle without introducing obvious distortion. By considering a −3 dBFS input sinusoidal signal with a frequency equal to BW, the ADC bandwidth can be calculated as

$${Δ}_{max} \cdot {f}_{CLK} = max \{ \frac{δ}{δ t} [ {A}_{- 3 dB} \cdot sin ( 2 π \cdot BW \cdot t ) ] \} \qquad ( 8 )$$

and therefore

$$BW = \frac{{Δ}_{max} \cdot {f}_{CLK}}{2 π \cdot {A}_{- 3 dB}} = \frac{L \cdot {Δ}_{min} \cdot {f}_{CLK}}{2 π \cdot {A}_{- 3 dB}} \qquad ( 9 )$$

where L is set to 5 in this example embodiment. Similar to the CT counterparts, the AR algorithm enables a bandwidth extension by a factor L compared to a fixed-resolution topology. It is also noted that given the minimum resolution, AR factor, input full scale, and clock frequency, the bandwidth of the quasi-LC delta modulator can be calculated rather precisely, which is in contrast to CT LC delta modulators, where the loop delay is instead a nonlinear function of the input signal derivative, and thus not constant.

The impact of AR in terms of ADC accuracy is reasonably negligible since it mainly entails higher harmonic distortion in a frequency range outside the signal bandwidth. In addition, the aforementioned low pass filtering of the preamplifier helps in further attenuating the out of band high frequency harmonics. It is observed that larger Δₘₐₓ chosen at the design stage would result in both a wider signal bandwidth and a lower average sampling rate as discussed infra, but it would in turn demand a preamplifier with a faster slew rate and wider output voltage range.

### Response Speed Comparison with SAR ADCs

In general, the aforementioned signal dependent oversampling behavior of LC ADCs allows to respond relatively quickly to any change in the input voltage that is larger than or equal to the distance between the neighboring levels, thus enabling real time monitoring of the signals to sense. For clockless CT LC delta modulators, the response time (t_{R}) can be as short as the minimum loop delay (t_{L,min}), while for the quasi-LC delta modulator of the present invention, it corresponds to T_{CLK}. For both the former and latter, delta A corresponds instead to the voltage shift at the feedback DAC output, which spans from 1× to L× of LSB_{DAC}. In the framework of real time monitoring sensing applications, a quantitative comparison between the quasi-LC ADC and uniform Nyquist sampling converters (i.e. SAR ADCs, given their state of the art power efficiency) can be carried out under the constraint of identical t_{R} (in both cases equal to T_{CLK}=f_{CLK}⁻¹) response to the same input voltage shift Δₘₐₓ (which is the maximum allowed for the quasi-LC ADC). In such a condition, the SAR ADCs would also need to be oversampled, thus dissipating more power, which would furthermore not depend on the input signal activity (to the first order) in most cases, except for the design. In contrast, LC ADCs feature power scalability versus the input signal activity, which is especially beneficial when sensing sparse signals. The OSR of the uniform sampling ADC counterparts would, therefore, be equal to the following

$${OSR}_{SAR} = \frac{{f}_{CLK}}{2 \cdot BW} = \frac{π \cdot {A}_{- 3 dB}}{{Δ}_{max}} . \qquad ( 10 )$$

Given that in the quasi-LC ADC, Δₘₐₓ=5·Δₘᵢₙ and A_{-3 dB}≈45·Δₘᵢₙ (since the feedback DAC nominal resolution is 7 bits), the equivalent SAR design should have an OSR of −28. Under the assumption that the SNDR of SAR ADCs is mainly limited by quantization noise, operating with an OSR of 28 (and scaling the BW accordingly) can lead to an increase of 14.5 dB in SNDR. As a consequence, the SAR ADC power efficiency would reduce approximately by a factor ˜5.27 (28/2^{14.5/6.02}). By considering, for the sake of comparison, only SAR ADCs with similar speed and resolution, their corresponding power efficiency would degrade, under these circumstances, down to 23.2, 38.5, and 89.6 fJ/c-s, respectively. In addition to this, the estimation does not consider the fact that the following digital block, which would be needed to perform the compressed sensing algorithm on the SAR ADC output, also consumes power. Therefore, for compressed sensing applications, the modulator can be a viable alternative to SAR ADCs. It is furthermore observed that for the targeted applications and in virtue of the operating principle of LC ADCs, the widely adopted Walden FoM (FoM_{W}) does not represent a faithful performance metric, since power scalability and average sampling rate compression, which are the peculiar features of LC ADCs, are not appropriately embedded into its expression.

### Dynamic Range (DR)

DR of the clockless CT LC delta modulators is upper bounded by the resolution of the feedback DAC (e.g., 8-bit). In flash LC ADCs, DR depends instead on the ratio between the largest Δₘₐₓ and smallest Δₘᵢₙ threshold intervals of the voltage quantizer. If the consecutive threshold levels in the flash based topology are equally spaced, then the DR is limited by the number of the comparators employed (e.g., 15). In the quasi-LC delta modulator, the smallest peak-to-peak signal amplitude (V_{IN,min}), which can be detected, is in the range of Δₘᵢₙ, Δₘᵢₙ₊₁, i.e. between 1 and 2 LSB_{DAC}, depending on the signal common mode voltage (V_{IN,CM}). If V_{IN,CM} lies right in the middle of two consecutive levels of the feedback DAC (V_{DAC,i} and V_{DAC,i+1}), then V_{IN,min} equals Δₘᵢₙ. Whereas if V_{IN,CM} is not equally spaced at V_{DAC,i} and V_{DAC,i+1}, then increases linearly as the distance between V_{IN,CM} and one of the two thresholds decreases, therefore, it is upper bounded by 2Δₘᵢₙ. Consequently, similar to the CT LC ADCs, the quasi-LC delta modulator exhibits a 6 dB DR variation, subject to V_{IN,CM} of input signal. Even in this regard, however, AR can be seen as a means of improving the DR of an LC ADC.

As it can be seen from Equation 9, if the ADC BW and the residue quantizer clock frequency are fixed, then the DR can be extended (i.e. smaller Δₘᵢₙ) by increasing the AR factor L. Therefore, the AR scheme helps to overcome the tradeoff between the DR and the signal bandwidth.

### Example Circuit Implementation

A block diagram of an example quasi-LC delta modulator constructed in accordance with the present invention is shown in FIG. 3. The residue quantizer is implemented as a 4-bit asynchronous top plate sampling SAR sub-ADC 73 (“4b sub-ADC”). Apart from the feedback DAC's digital control code (D_{OUT}), AR Comp 82 also generates an “event based” output signal EB_{OUT} comprising the trigger CNG going high if a level is crossed, signal UD indicating a positive or negative input derivative, and \tilde{Δ} indicating the magnitude of the shift that D_{OUT} experienced during the CLK period. A custom digital control block 70 (“Custom Ctrl Logic”) is used to generate the 12.5% duty cycle clock signal for the residue quantizer (CLK), to gate off CLK with the CNG event trigger from AR Comp, thus generating CLK_event, and to finally produce the nonoverlapping replicas of CLK_event (CLK1 and CLK2) responsible for controlling the sw-cap feedback DAC and subtractor 62.

### Switched Capacitor Feedback DAC and Subtractor

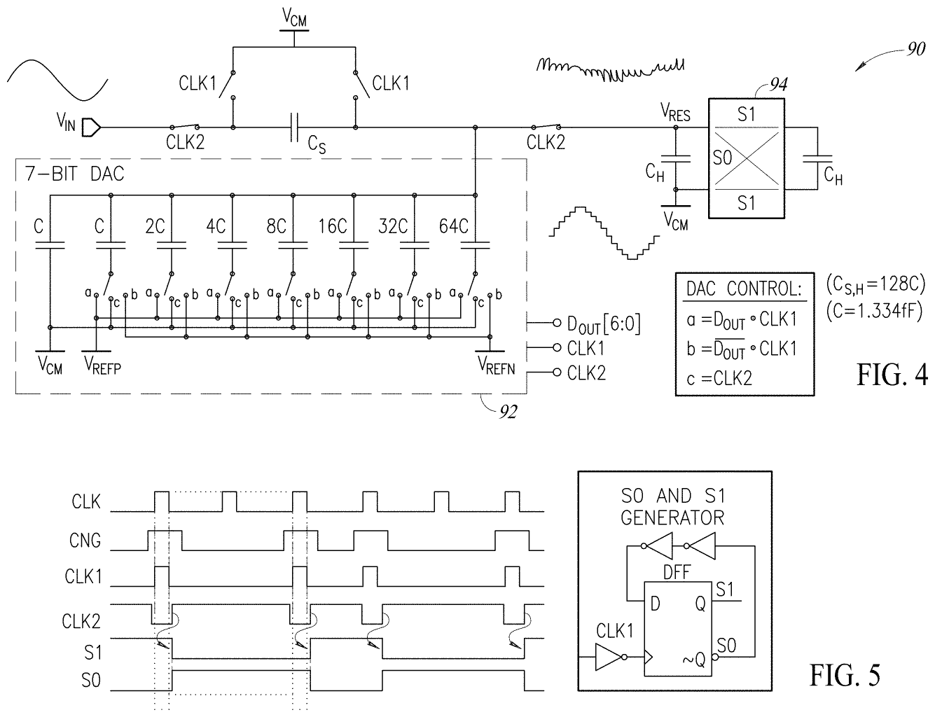

Example implementations of the charge redistribution sw-cap feedback DAC and subtractor are shown in FIGS. 4 and 5. The digital control signals, including CLK1, CLK2, s0, and s1, are all derived from the LC trigger CNG and system clock CLK. There are two operational phases: track and update. When a digital threshold level in the AR Comp is crossed, CNG is asserted, thus generating CLK1 as a gated version of CLK. Likewise, CLK2 is a nonoverlapping inverted replica of CLK1. The rising edge of CLK1 asserts the update phase of the DAC 92. During this phase, depending on the digital binary output D_{OUT} of U/D COUNT, the bottom plates of the DAC capacitors are connected to V_{REFP} or V_{REFN}, while the input capacitor C_{S} is shorted to V_{CM}. Moreover, the hold capacitor C_{H} maintains the value that node V_{RES} captured right before the end of the previous track phase. At the rising edge of CLK2, the subtraction between V_{IN} and the sw-cap DAC output V_{DAC} (stored on its binary weighted capacitors C . . . 64C) is performed, which marks the beginning of the track phase. Synchronously to this, the control signals s0 and s1 also change state, inducing the flipping of the rightmost C_{H} capacitor, thus removing the memory charge. During the track phase, V_{RES} is a CT signal and is equal to

V_{RES}(t)=G_{S}·[V_{IN}(t)−V_{DAC}]+V_{CM} (11)

where V_{DAC} is equal to LSB_{DAC}·Σᵢ₌₀⁶(D_{OUT}[i]·2ⁱ) and G_{S} is ¼.

The unit capacitance C is equal to 1.334 fF, and it is implemented as a MOM-cap in metal layers M4 to M6 from the process design kit (PDK). The value of the two hold capacitors C_{H} is 170.7 fF (i.e. 128C), which ensures that the standard deviation of mismatch between the two C_{H}'S is only 0.1%, meaning the voltage error at V_{RES} due to the memory charge after the flipping of the second C_{H} (the rightmost C_{H} in FIG. 4) is ≤30 μV (considering a 3σ variation) and can therefore be ignored. As bulk CMOS technology scales, however, the drain (source) to gate (I_{gd,leak}), drain (source) to bulk (I_{bd,leak}), and subthreshold (off) drain to source (I_{off}) leakage current densities of the CMOS switches increase. Although the impact of the latter is negligible, since the residue voltage V_{RES} is in a small range around V_{CM} during the track phase, both the former leakage components (reasonably signal independent) from all the switches asserting to V_{RES} lead to the loss of the charge information stored on C_{H}.

### Maximum Voltage Error

It is noted that the maximum voltage error of V_{RES} caused by the sum of all these accumulating spurious leakage currents (I_{leakage}) is upper bounded by ΔV_{err,max}=LSB_{DAC}/4 (or equivalently Δₘᵢₙ/4 where the factor 4 stems from α·G_{A}). To aid in understanding this, consider the sole effect of leakage on node V_{RES}, and assume, without loss of generality, that the sign of I_{leakage} is such that V_{RES} is linearly increasing, and that the track phase has just been asserted. Therefore, the subsequent update phase will only be asserted when the residue quantizer sub-ADC “senses” a positive voltage shift of its input (i.e. the amplified residue voltage G_{A}·V_{RES}) equal to LSB_{sub-ADC}, implying α·G_{A}·V_{RES}=α·LSB_{sub-ADC}=LSB_{DAC} (where α·G_{A} is nominally equal to 4). As a consequence, the loop reacts by increasing by 1 the feedback DAC digital input D_{OUT}, thus causing a negative voltage shift of V_{RES}. Such a shift would trigger another LC event, with D_{OUT} being decremented by 1 and consequently V_{RES} restored back to its initial correct value of V_{CM}. This mechanism produces a sawtooth voltage pattern at node V_{RES} which acts as a dithering signal for the slowly varying input signal, ultimately resulting in a small increase in power consumption.

### Maximum Hold Time

The above mentioned effect of leakage current is particularly harmful at the turning point of a low frequency input signal since the rate of change of V_{RES} caused by the linear charge (i.e. discharge) due to I_{leakage} can be comparable, or even considerably higher, than that caused by the slow ADC input signal. We can therefore define with T_{H,max} the maximum hold time allowed for node V_{RES} before the accumulated leakage current would trigger an LC event (i.e. the time needed for I_{leakage} to make V_{RES} vary by an amount equal to V_{err,max}) and expressed it as

$${T}_{H , max} = \frac{Δ {V}_{err , max} \cdot {C}_{H , total}}{{I}_{leakage}} = \frac{{Δ}_{min} \cdot {C}_{H , total}}{4 \cdot {I}_{leakage}} \qquad ( 12 )$$

where C_{H,total} is the total hold capacitor at node V_{RES}, which includes C_{S}, both the C_{H} capacitors, the total DAC capacitance, and any routing/parasitic capacitance, for an overall value of ˜680 fF.

### Input Referred Voltage Error

The input referred voltage error caused by the above mentioned leakage current increases linearly with time. When the track phase hold time reaches its maximum T_{H,max} such error has an rms value of LSB_{DAC}/\sqrt{3}. A first order approximation of this voltage error at the modulator output can be derived by considering the average hold time T_{H,avg,in} between two consecutive level crossing events in the absence of current leakage i.e. only due to the input signal. Its power can be expressed as

$$P ( {δ}_{leakage} ) = {( \frac{{T}_{H , avg , in}}{{T}_{H , max}} \cdot \frac{{LSB}_{DAC}}{\sqrt{3}} )}^{2} . \qquad ( 13 )$$

This power is distributed over a frequency range that can span up to a frequency BWₗₑₐₖ (hereinafter referred to as leakage bandwidth) equal to the inverse of the minimum time between the consecutive level crossing events T_{H,min,in}⁻¹ whose maximum value corresponds to the clock frequency. This is because according to the pseudo-CT operation of the quasi-LC ADC, T_{H,min,in} cannot be lower than T_{CLK}. For a sinusoidal input signal with peak-to-peak amplitude A_{in,pp} and frequency fₖᵢₙ, T_{H,avg,in} and T_{H,min,in} can be expressed as

$$\begin{matrix}{T}_{H , avg , in} = \frac{FS}{{f}_{in} \cdot {A}_{in , pp} \cdot {2}^{N + 1}} & ( 14 ) \\ {T}_{H , min , in} = \frac{{Δ}_{min}}{π \cdot {f}_{in} \cdot {A}_{in , pp}} & ( 15 )\end{matrix}$$

where FS is the modulator full scale range and Nis the resolution of the feedback DAC, equal to 7 in this design. Note that in Equations 14 and 15 and for the sake of simplicity, we have assumed that fᵢₙ is such that the AR is not asserted, which justifies the use of the factor 2^{N+1} in the denominator of Equation (14) (i.e. the number of levels crossed in one period of a full scale input sinewave) and Δₘᵢₙ in that of Equation (15). It is therefore evident that the leakage bandwidth depends on the input signal characteristics (e.g., frequency and amplitude) and, in the example of a −3 dBFS input sinewave, it is equal to the signal bandwidth BW for fᵢₙ=5 kHz, meaning that all the leakage error power falls in-band when fᵢₙ<5 kHz. By substituting Equations 12 and 15 into Equation (13), P(δ_{leakage}) can be rewritten in the form

$$P ( {δ}_{leakage} ) = {( \frac{4 \cdot {I}_{leakage} \cdot FS}{{2}^{N + 1} \cdot {A}_{in , pp} \cdot {C}_{H , total} \cdot {f}_{in} \cdot \sqrt{3}} )}^{2} \qquad ( 16 )$$

which once again supports the intuition that for a given design of the sw-cap feedback DAC and subtractor, which implies certain I_{leakage}, C_{H,total}, and FS, the error power caused by the leakage current of the switches only depends on the input signal characteristics (e.g., frequency and amplitude), suggesting that the SNR of the quasi-LC delta modulator degrades at low signal frequencies. Equation 16, however, also seems to suggest that P(δ_{leakage}) grows infinitely as fᵢₙ goes to zero. In reality, as stated earlier, the maximum voltage error at node V_{RES} due to the leakage is bounded by LSB_{DAC}/4, and the maximum of T_{H,avg,in} is T_{H,max}. Based on Equation 13, the maximum power of voltage error at the modulator output caused by the leakage is ⅓·LSB_{DAC}², which falls completely within the signal bandwidth of the modulator, thus resulting in a lower bounded SNR caused by leakage (SNR_{leakage}) of about 38 dB.

Circuit simulations indicate a nominal value of I_{leakage} of approximately 70 pA, which leads to a nominal T_{H,max} of about 19 μs. By increasing C_{H,total} (whose size is tied to the unit cap C) and by reducing the size of the switches so as to decrease I_{leakage}, the implemented sw-cap feedback DAC and subtractor can support even lower signal bandwidths (i.e. biomedical implantable devices). The size of the switches and of the unit cap C determines the tradeoff between the leakage error power at low signal frequency and the modulator distortion arising from the incomplete settling of the sw-cap DAC and subtractor.

Although the above mentioned analysis focuses on the low frequency impairments of the quasi-LC ADC, the SNDR in the midband region of the spectrum is also a function of the signal path gain Gₜₒₜₐₗ and it is moreover affected not only by the resolution of the sw-cap feedback DAC, which directly relates to the odd harmonics of the modulator, but also by the nonlinearity of the sw-cap feedback DAC and subtractor, whose harmonic distortion (i.e. SFDR of about 60 dB) directly impacts the delta modulator output.

### Preamplifier

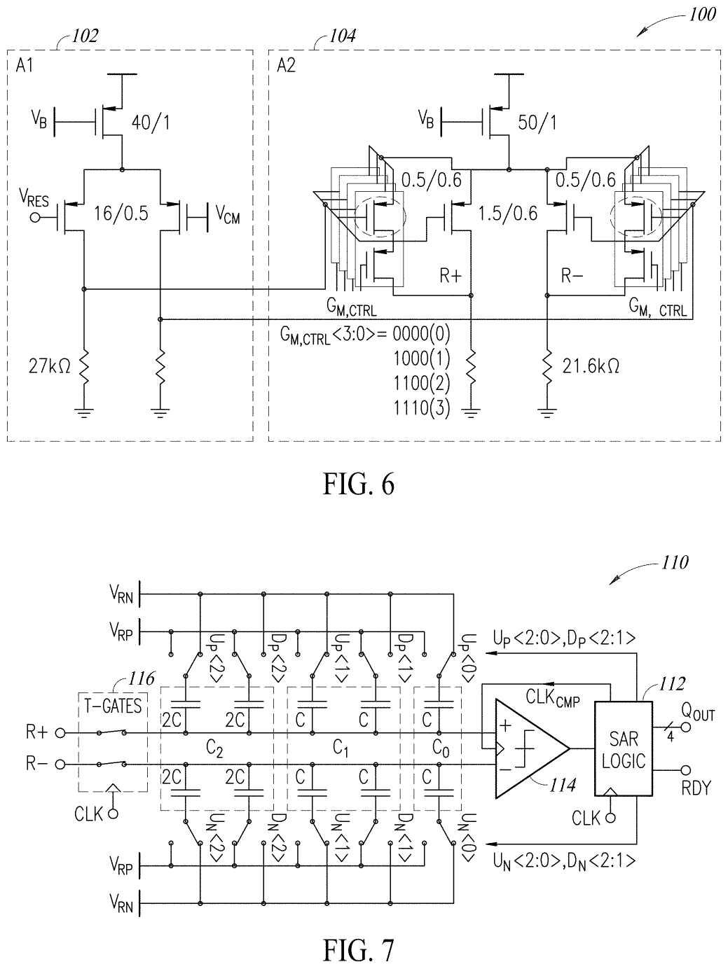

The preamplifier serves the purpose of amplifying the residue voltage V_{RES} converting the single ended residue voltage to differential and driving the input capacitance of the differential asynchronous SAR residue quantizer behaving as an LPF in front of residue quantizer. As shown in FIG. 3, the preamplifier consists of two stages (A1 and A2), each with a nominal dc gain of two, and whose detailed implementation is shown in FIG. 6. As discussed earlier, the gain and pole frequencies of the preamplifier determine the NTF and STF characteristics of the delta modulator. A PVT induced deviation of the signal path gain Gₜₒₜₐₗ from its nominal value can be accommodated by adjusting the amplitude of LSB_{sub-ADC} (tuning V_{RP} and V_{RN}, with reference to FIG. 3), as well as by tuning the aspect ratio of the input differential pair transistors of A2 (therefore the transconductance) for the situation that V_{RP} and V_{RN} need to be fixed, which allows α·G_{A}·G_{S} to be restored to unity.

This is implemented in one embodiment utilizing a bank of five parallel PMOS transistors, three of which can be disconnected from the output node of A2 with PMOS switches in series to their drains, controlled by the digital code G_{m,CTRL} (active low). This tuning scheme is only implemented in A2, as the parasitic capacitor at V_{RES} would lead to gain deviation of G_{S} and memory charge on capacitor C_{H}. Note that such a tuning scheme is also effective in compensating for variations in the frequency of dominant poles, since increasing the number of PMOS transistors connected in parallel also increases the load capacitance of A1. From G_{m,CTRL}=0 to G_{m,CTRL}=3, G_{A2} drops by 50%, while the load capacitor of A1 decreases by approximately 20% (neglecting the parasitic capacitance). For conventional LC ADCs, the offsets of CT comparators cause shifts of the threshold levels, ultimately leading to nonlinearity. Therefore, an offset calibration protocol is required.

In the modulator of the present invention, the offset of preamplifier and residue quantizer can be treated as an input dc voltage shift, which only leads to an offset in the digital binary output code of U/D CNT (D_{OUT}) and which has no impact on linearity. From the value G_{m,CTRL}=0 to G_{m,CTRL}=3, the input referred in-band noise of the preamplifier increases by 16%, from 20.94 μVrms to 24.3 μVrms, respectively, mainly contributed by flicker noise, as the effective size of the input MOS transistors of stage A2 decreases (less transistors connected in parallel). Considering, however, that the power of this noise is much smaller than that of the in-band quantization noise contributed by the residue quantizer, its effect on the system SNR can be neglected.

### SAR-Based Residue Quantizer

In the quasi-LC ADC, the residue quantizer converts the amplified residue voltage into a 4-bit digital information (Qₒᵤₜ). The choice of 4 bits relies on the chosen AR factor (one sided L=5) demanding ten threshold levels in accordance with the equivalent model presented in FIG. 1D. The clock frequency of 80 MHz is chosen to allow all 4 bits to be resolved (i.e. ensuring that the conversion ready output trigger RDY is always asserted within a clock period), and accounting for a reasonable time margin to cope with process variations. The residue quantizer is implemented as a top plate sampling asynchronous SAR ADC with split binary weighted capacitive DAC (apart from the LSB capacitors C₀, which are not split), as shown in FIG. 7. The choice of the successive approximation topology relies on its simplicity, amenability to process scaling and state-of-the-art power efficiency.

The unit capacitor of the residue quantizer capacitive DAC is a 4.5 fF metal-oxide-metal (MOM)-cap from the process design kit (PDK), while the sampling switches are simple transmission gates. Given the low resolution of sub-ADC, as well as the low amplitude of the amplified V_{RES} (well below the ADC's full scale range), switch boot strapping is not necessary. The comparator is implemented as a simple latch stage, while the SAR logic consists of only TSPC (true single phase clock) flip flops and logic gates. Because of oversampling (f_{CLK} is about 56×BW), the contribution of the residue quantizer quantization noise power to the proposed LC ADC's SNR is given by

$${SNR}_{SAR , dB} = 6.02 N + 1.76 + 10 log ( \frac{{f}_{CLK}}{2 \cdot BW} ) \qquad ( 17 )$$

where N is the resolution of the sw-cap feedback DAC. For BW=1.42 MHz, SNR_{SAR}=58 dB which is the upper bound of the SNR of the quasi-LC ADC. With reference to Equation 2, a conventional LC ADC with equal bandwidth would demand a loop delay dispersion Δtₑ lower than 173 ps to achieve the same SNR, which is relatively difficult to obtain with a multistage comparator topology, and would need to be traded off with the comparators' bandwidth and power consumption. For example, a four-stage comparator in the LC ADC could achieve a delay dispersion of around 150 ps with a bandwidth of 200 MHz when the ADC converts a 20 MHz full scale input sinewave. In the modulator of the present invention, the quantization noise of the residue quantizer dominates the SNR at signal frequencies in the upper range of the signal bandwidth of the modulator, while for low input frequencies, the ADC SNR is instead dominated by the voltage error caused by the current leakage of the switches within the sw-cap subtractor, as discussed earlier.

### AR Comparator and Up/Down Counter

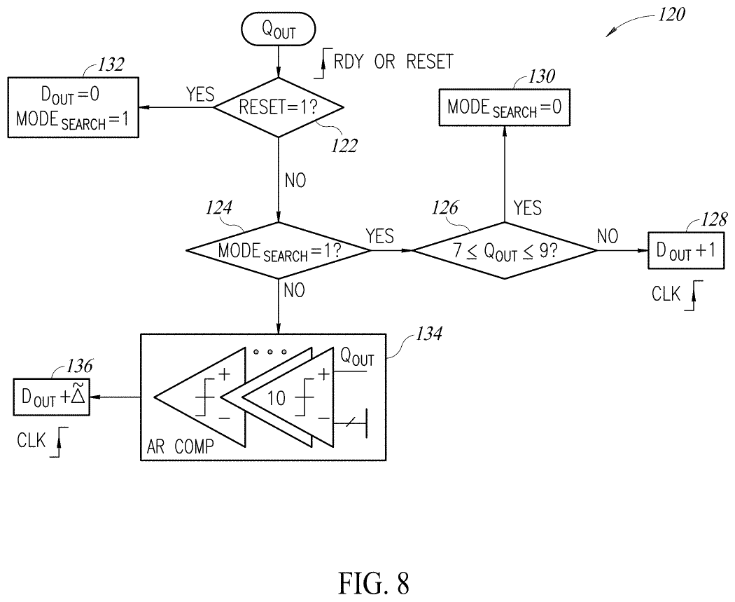

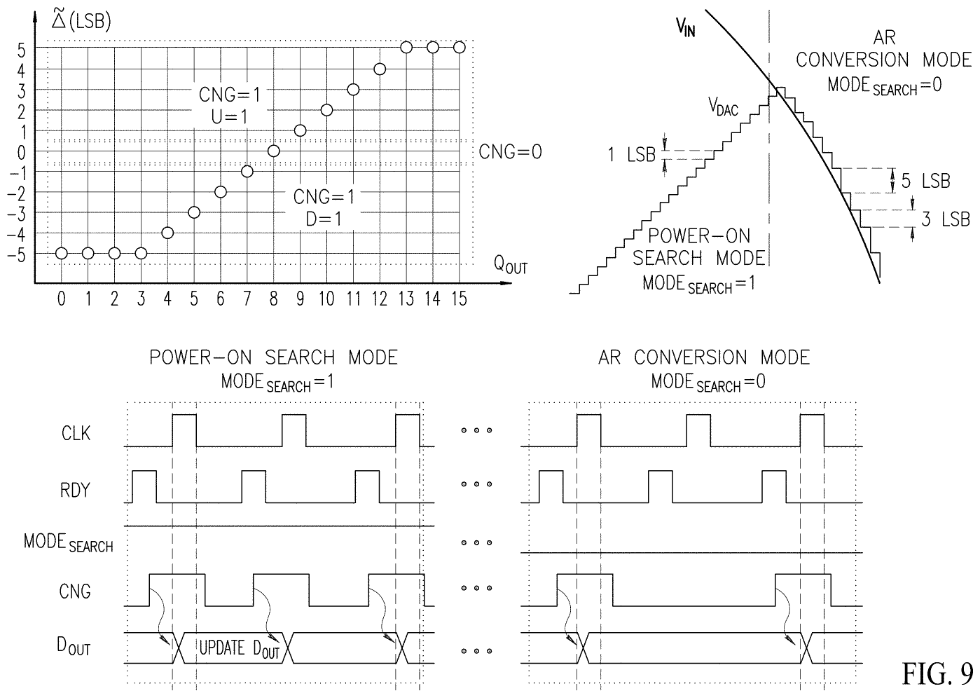

FIGS. 8 and 9 show a flow diagram of the synthesized digital logic an related timing diagrams. At system reset (Reset, e.g., power-ON reset or user interrupt), a power-ON search mode is asserted by setting Mode_{SEARCH} to 1 at the rising edge of Reset. The U/D counter then increments at each rising edge of CLK until the feedback DAC output “locks” within 1 LSB_{DAC} away from V_{IN} or, alternatively, until |V_{RES}−V_{CM}|≤Δₘᵢₙ/4. This ends the power-ON search mode and asserts the normal AR conversion mode (Mode_{SEARCH}=0). In this operational phase, when RDY=1 is asserted, the digital comparison is performed between Q_{OUT} and the ten thresholds of the AR Comp (9, 10, . . . 13 and 3, 4, . . . 7; see FIG. 9), which are the digital equivalents of the “levels” of an LC ADC with reference to FIG. 1D. This will end in generating the event based digital output signal EB_{OUT}. This whole sequence of operations must be completed before the next rising edge of CLK, which triggers the update of the U/D counter output D_{OUT}, according to EB_{OUT}.

### ECG Example Waveform

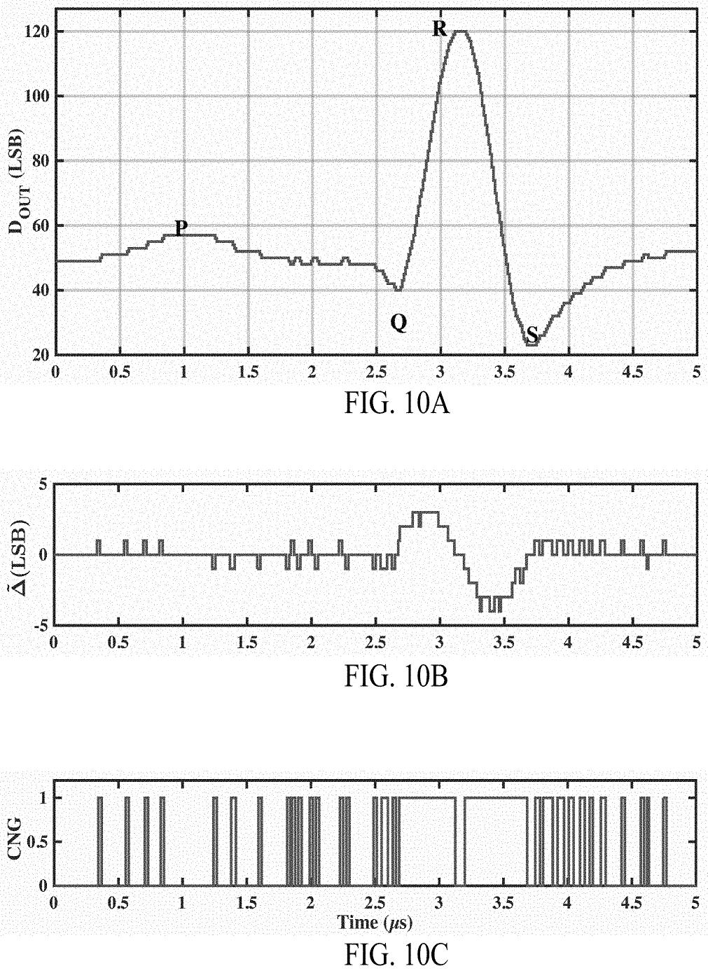

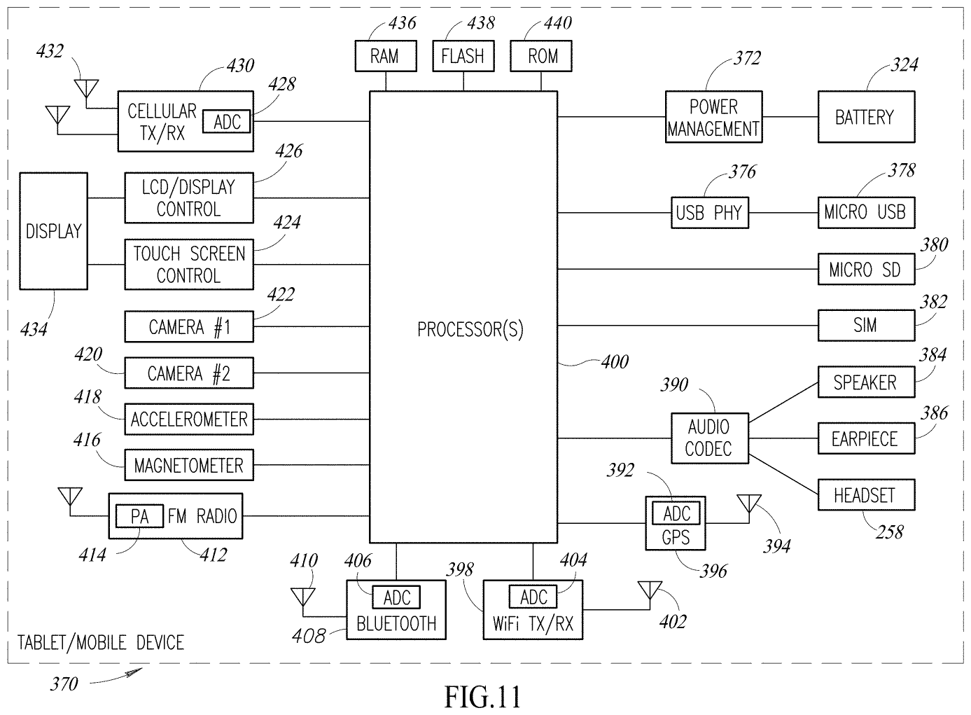

Given the intended use of the quasi-LC ADC for digitizing signals which are sparse in time and with a low to medium accuracy, it is illustrative to show its behavior with relevant signals, e.g., an electrocardiogram (ECG) like shape generated via an arbitrary waveform generator. The ECG signal frequency has been intentionally increased to visualize the operation of the AR algorithm in the regions of high signal derivative (i.e. coarser resolution for high signal derivatives and finer resolution at low derivatives). The measured 7-bit digital binary output D_{OUT} and the event-based output EB_{OUT} are shown in FIGS. 10A, 10B, and 10C, demonstrating that the AR algorithm is enabled only when the input signal changes rapidly, as visible when \tilde{Δ} (the direction information is included in UD) becomes higher than 1 or lower than −1 (e.g., between the Q and R and between the R and S intervals). Moreover, the event trigger CNG is kept low when no level crossing occurs.

### Mobile Device Incorporating the Event Driven Quasi-LC Delta Modulator ADC

A block diagram illustrating an example tablet/mobile device incorporating the event driven quasi-LC delta modulator ADC of the present invention is shown in FIG. 11. The mobile device is preferably a two-way communication device having voice and/or data communication capabilities. In addition, the device optionally has the capability to communicate with other computer systems via the Internet. Note that the mobile device may comprise any suitable wired or wireless device such as multimedia player, mobile communication device, digital still or video camera, cellular phone, smartphone, iPhone, PDA, PNA, Bluetooth device, tablet computing device such as the iPad or other iOS device, Android device, Surface, Nexus, Google Glass, etc. For illustration purposes only, the device is shown as a mobile device, such as a cellular based telephone, smartphone or superphone. Note that this example is not intended to limit the scope of the mechanism as the invention can be implemented in a wide variety of communication devices. It is further appreciated the mobile device shown is intentionally simplified to illustrate only certain components, as the mobile device may comprise other components and subsystems beyond those shown.

The mobile device, generally referenced 370, comprises one or more processors 400 which may comprise a baseband processor, CPU, microprocessor, DSP, etc., optionally having both analog and digital portions. The mobile device may comprise a plurality of cellular radios 430 and associated antennas 432. Radios for the basic cellular link and any number of other wireless standards and Radio Access Technologies (RATs) may be included. Examples include, but are not limited to, Third Generation (3G) Long Term Evolution (LTE), Code Division Multiple Access (CDMA), Personal Communication Services (PCS), Global System for Mobile Communication (GSM)/GPRS/EDGE 3G; WCDMA; WiMAX for providing WiMAX wireless connectivity when within the range of a WiMAX wireless network; Bluetooth for providing Bluetooth wireless connectivity when within the range of a Bluetooth wireless network; WLAN for providing wireless connectivity when in a hot spot or within the range of an ad hoc, infrastructure or mesh based wireless LAN (WLAN) network; near field communications; UWB; GPS receiver for receiving GPS radio signals transmitted from one or more orbiting GPS satellites, FM transceiver provides the user the ability to listen to FM broadcasts as well as the ability to transmit audio over an unused FM station at low power, such as for playback over a car or home stereo system having an FM receiver, digital broadcast television, etc.

The mobile device may also comprise internal volatile storage 436 (e.g., RAM) and persistent storage 440 (e.g., ROM) and flash memory 438. Persistent storage 436 also stores applications executable by processor(s) 400 including the related data files used by those applications to allow device 370 to perform its intended functions. Several optional user-interface devices include trackball/thumbwheel which may comprise a depressible thumbwheel/trackball that is used for navigation, selection of menu choices and confirmation of action, keypad/keyboard such as arranged in QWERTY fashion for entering alphanumeric data and a numeric keypad for entering dialing digits and for other controls and inputs (the keyboard may also contain symbol, function and command keys such as a phone send/end key, a menu key and an escape key), headset 388, earpiece 386 and/or speaker 384, microphone(s) and associated audio codec 390 or other multimedia codecs, vibrator for alerting a user, one or more cameras and related circuitry 420, 422, display(s) 434 and associated display controller 426 and touchscreen control 424. Serial ports include a micro USB port 378 and related USB PHY 376 and micro SD port 380. Other interface connections may include SPI, SDIO, PCI, USB, etc. for providing a serial link to a user's PC or other device. SIM/RUIM card 382 provides the interface to a user's SIM or RUIM card for storing user data such as address book entries, user identification, etc.

Portable power is provided by the battery 324 coupled to power management circuitry 372. External power is provided via USB power or an AC/DC adapter connected to the power management circuitry that is operative to manage the charging and discharging of the battery. In addition to a battery and AC/DC external power source, additional optional power sources each with its own power limitations, include: a speaker phone, DC/DC power source, and any bus powered power source (e.g., USB device in bus powered mode).

Operating system software executed by the processor 400 is preferably stored in persistent storage (i.e. ROM 440), or flash memory 438, but may be stored in other types of memory devices. In addition, system software, specific device applications, or parts thereof, may be temporarily loaded into volatile storage 436, such as random access memory (RAM). Communications signals received by the mobile device may also be stored in the RAM.

The processor 400, in addition to its operating system functions, enables execution of software applications on the device 370. A predetermined set of applications that control basic device operations, such as data and voice communications, may be installed during manufacture. Additional applications (or apps) may be downloaded from the Internet and installed in memory for execution on the processor. Alternatively, software may be downloaded via any other suitable protocol, such as SDIO, USB, network server, etc.

Other components of the mobile device include an accelerometer 418 for detecting motion and orientation of the device, gyroscope 417 for measuring or maintaining orientation, magnetometer 416 for detecting the earth's magnetic field, FM radio 412 and antenna 413, Bluetooth radio 408 and antenna 410, Wi-Fi radio 398 including antenna 402 and GPS 392 and antenna 394.

In accordance with the invention, the mobile device 370 comprises one or more circuits, each incorporating the event driven quasi-LC delta modulator ADC of the present invention described in detail supra. Numerous embodiments of the mobile device 370 may comprise an ADC circuit 428 as described supra incorporated in the one or more cellular radios 430; an ADC circuit 414 as described supra incorporated in the FM radio 412; an ADC circuit 406 as described supra incorporated in the Bluetooth radio 408; an ADC circuit 404 as described supra incorporated in the Wi-Fi radio 398; and an ADC circuit 396 as described supra incorporated in the GPS radio 392. Note that one or more additional quasi-LC ADCs can be added such as to monitor vital signs of the user. With the miniaturization of the mobile device components, it is now becoming possible to fit the mobile device 370 into relatively small form factors such as a wrist watch.

### Internet of Things (IoT) Node Incorporating the Power Amplifier

The Internet of Things (IoT) is defined as the network of physical objects or “things” embedded with electronics, software, sensors and network connectivity, which enables these objects to collect and exchange data. The IoT allows objects to be sensed and controlled remotely across existing network infrastructure, creating opportunities for more direct integration between the physical world and computer-based systems, and resulting in improved efficiency, accuracy and economic benefit. Each thing is uniquely identifiable through its embedded computing system but is able to interoperate within the existing Internet infrastructure. Experts estimate that by the end of 2021, 31 billion new IoT devices will be installed around the world.

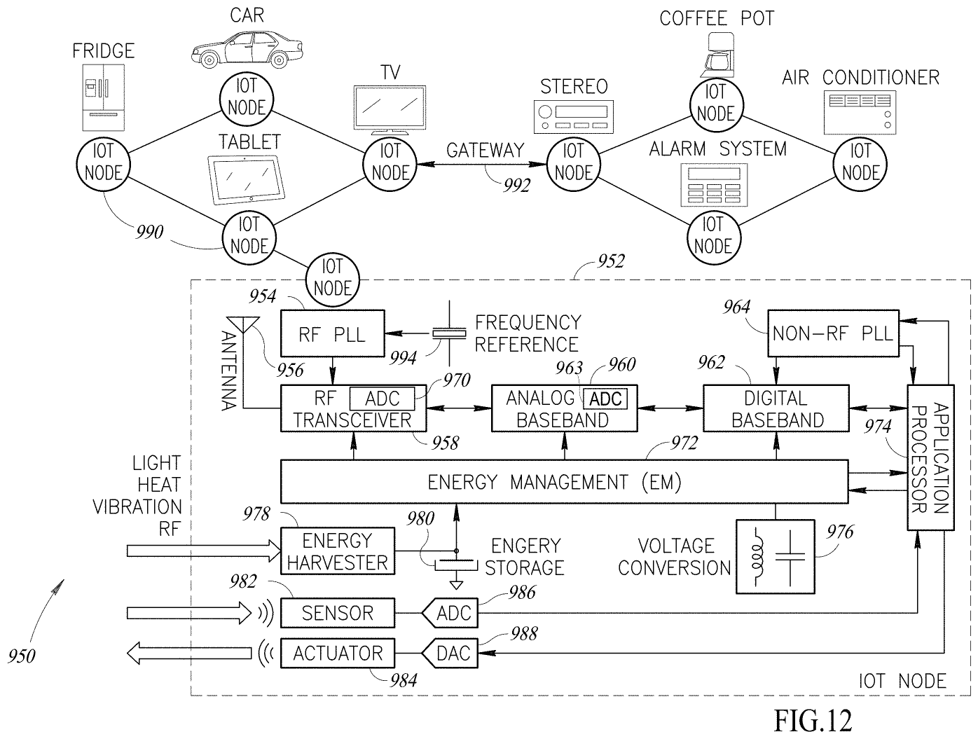

A block diagram illustrating an example IoT node incorporating the event driven quasi-LC delta modulator ADC of the present invention is shown in FIG. 12. The example IoT, generally referenced 950, comprises a plurality of nodes 990. The architecture of an example IoT node 952 shown can be fully integrated as a System on Chip (SoC) on a single IC chip in nanoscale CMOS. It contains the radio subsystem to wirelessly communicate with other nodes and gateways 992, application processor to impart a certain amount of local “intelligence”, sensor and an optional actuator to interface with the environment and energy management to harvest energy (light, heat, vibration or RF power) from the environment and/or convert the voltage levels to those required by the functional circuitry. The RF and non-RF frequency synthesizers provide local oscillator and processor clocks, respectively. A frequency reference 994 provides a fixed clock with excellent long term stability to the frequency synthesizers. In one embodiment, the ADC of the present invention described supra is incorporated in the analog baseband 960 as circuit block 963. It can also be incorporated in the RF transceiver block 958 as circuit block 970. It is also incorporated as the ADC 986 in the IoT node 952.

The RF transceiver 958 interfaces with an antenna 956. The RF signals are upconverted and downconverted there to the lower (i.e. baseband) frequencies, which are then processed in the analog baseband circuitry. The digital baseband completes the physical layer of a chosen communication standard. The application processor performs various control and signal processing functions and is responsible for giving a level of “intelligence” to the IoT node. The conversion from analog to digital (i.e. ADC 986), and vice versa (i.e. DAC 988), is also performed in the IoT node for sensing and actuation.

The RF frequency synthesizer 954 is realized as an all-digital PLL (ADPLL) and provides a local oscillator signal to the RF transceiver 958. The non-RF frequency synthesizer 964 provides clocks to the digital baseband 962 and application processors 974. The clock frequency has to be dynamically switchable in response to the changing computational load conditions. The energy management (EM) circuitry 972 provides energy conversion between the energy harvester 978 and/or low-capacity storage battery 980 and all the IoT functional circuits. The EM circuit carries out several functions. First, it boosts the voltage from the energy harvester (e.g., light, heat, vibration, RF electromagnetic, etc.) to that required by the nanoscale CMOS circuits, which is in the range of 0.7 to 1.0 V assuming 40 nm CMOS technology. This is performed by a dedicated DC-DC boost converter 976. Second, it down-shifts the energy from a battery, which is on the order of 1.5 to 3.6 V to that required by the nanoscale CMOS circuits. This is performed by a dedicated DC-DC buck converter 976. Third, both boost and buck converters use energy storage passive devices, i.e. capacitor or inductor for storing electrical and magnetic energy, respectively, in order to change the voltage level with high efficiency. The high conversion efficiency must be maintained across the entire range of the allowed loads. Fourth, the EM needs to provide many power supply domains. This is dictated by the different voltage level requirements during voltage scaling. Fifth, the EM supply domains preferably provide individually adjustable voltage levels. The supply voltage level of digital logic circuits widely vary depending on the fast changing real time computational load conditions, while the voltage level of digital RF and analog circuits experience less of such variance, and mainly due to temperature and operating frequency, as well as communication channel conditions. Moreover, the analog circuits have to be properly biased, which normally prevents them from operating at near-threshold conditions.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. As numerous modifications and changes will readily occur to those skilled in the art, it is intended that the invention not be limited to the limited number of embodiments described herein. Accordingly, it will be appreciated that all suitable variations, modifications and equivalents may be resorted to, falling within the spirit and scope of the present invention. The embodiments were chosen and described in order to best explain the principles of the invention and the practical application, and to enable others of ordinary skill in the art to understand the invention for various embodiments with various modifications as are suited to the particular use contemplated.

What is claimed is:

1. An analog to digital converter (ADC) circuit, comprising:
a subtractor operative to subtract an analog feedback signal generated by a digital to analog converter (DAC) from an input voltage signal to generate a residue signal;
a residue quantizer operative to convert said residue signal from an analog to digital domain;
an event detector operative to detect when said residue signal crosses one of a plurality of levels; and
an up/down counter operative to change a digital output in accordance with said level crossing detection, said digital output fed back to an input of said DAC.

2. The ADC circuit according to claim 1, further comprising a preamplifier operative to amplify said residue signal before input to said residue quantizer.

3. The ADC circuit according to claim 1, wherein said DAC comprises a 7-bit switched capacitor based DAC.

4. The ADC circuit according to claim 1, wherein said residue quantizer comprises a relatively low resolution successive approximation register (SAR) sub-ADC.

5. The ADC circuit according to claim 1, wherein said event detector is operative to compare said residue signal to ten digital threshold levels.

6. The ADC circuit according to claim 1, further comprising a circuit operative to perform an adaptive resolution level crossing algorithm in the digital domain.

7. An analog to digital converter (ADC), comprising:
a subtraction node adapted to subtract the output of a feedback digital to analog converter (DAC) from an input voltage signal;
a clocked residue quantizer adapted to convert the output of said residue amplifier from analog to digital domain; and
an adaptive resolution circuit incorporating a delta modulator circuit and adapted to perform level crossing and adaptive resolution algorithms in the digital domain to generate a digital output therefrom.

8. The ADC circuit according to claim 7, further comprising a residue amplifier adapted to amplify the output of said subtraction node.

9. The ADC circuit according to claim 7, wherein said preamplifier comprises sufficient gain to compensate for passive losses from said subtraction node.

10. The ADC circuit according to claim 7, wherein said DAC comprises a 7-bit switched capacitor based DAC.

11. The ADC circuit according to claim 7, wherein said residue quantizer comprises a 4-bit successive approximation register (SAR) sub-ADC.

12. The ADC circuit according to claim 7, wherein said an adaptive resolution circuit is operative to compare said residue signal to ten digital threshold levels.

13. The ADC circuit according to claim 7, wherein said adaptive resolution circuit generates one or more up/down control signals input to an up/down counter operative to generate said digital output.

14. A method of analog to digital conversion, the method comprising:
subtracting an analog feedback signal generated by a digital to analog converter (DAC) from an input voltage signal to generate a residue signal;
converting said residue signal from an analog to digital domain;
detecting when said residue signal crosses one of a plurality of levels; and
changing a digital output in accordance with said level crossing detection, said digital output fed back to an input of said DAC.

15. The method according to claim 14, further comprising amplifying said residue signal before conversion to the digital domain.

16. The method according to claim 14, wherein said DAC comprises a 7-bit switched capacitor based DAC.

17. The method according to claim 14, wherein said detection comprises comparing said residue signal to ten digital threshold levels.

18. The method according to claim 14, further comprising performing an adaptive resolution level crossing algorithm in the digital domain.
